(19) United States
(12) Patent Application Publication
(10) Pub. No.: US 2013/0180772 A1
(43) Pub. Date: Jul. 18, 2013

(54) WIRING BOARD AND METHOD OF MANUFACTURING THE SAME

(71) Applicant: NGK Spark Plug Co., Ltd., Nagoya-shi (JP)

(72) Inventors: Masahiro INOUE, Kounan-shi (JP); Atsuhiko SUGIMOTO, Kagamigahara-shi (JP)

(73) Assignee: NGK SPARK PLUG CO., LTD., Nagoya-shi (JP)

(21) Appl. No.: 13/719,665

(22) Filed: Dec. 19, 2012

(30) Foreign Application Priority Data
Dec. 20, 2011 (JP) 2011-277969
Nov. 6, 2012 (JP) 2012-244933

(51) Int. Cl. H05K 1/11

(52) U.S. Cl. CPC H05K 1/111
USPC 174/263; 228/256

(57) ABSTRACT

Embodiments provide a wiring board which is structured to be suitable for connection with components, whereby its reliability can be improved. An embodied wiring board of the invention has pads and a solder resist in which opening portions which expose the pads are formed. Protrusion-shaped members are fixed to some of the surfaces of the pads. The surfaces of the pads and the surfaces of the protrusion-shaped members are covered with solder bumps. The height of the solder bumps is larger than the height H1 and H2 of the protrusion-shaped members. The opening portions have different inner diameters, and the volume of the protrusion-shaped members increases as the diameter of the opening portion decreases.

### CROSS REFERENCE TO RELATED APPLICATIONS

The present application claims priority from Japanese Patent Application No. 2011-277969, which was filed on Dec. 20, 2011, and Japanese Application No. 2012-244933, which was filed on Nov. 6, 2012, the disclosures of which are incorporated by reference in their entirety.

### BACKGROUND OF THE INVENTION

1. Field of the Invention

The present invention relates to a wiring board having a plurality of pads disposed in an electrode-forming area on the substrate main surface thereof and a method of manufacturing the same.

2. Description of Related Art

In the past, a wiring board formed by mounting components, such as IC chips (a so-called semiconductor package), was well known. As a structure for achieving electrical connection with IC chips, a structure in which solder bumps are formed on a plurality of connection terminals disposed on the bottom surface side of the IC chips or on a plurality of pads (so-called C4 pads: Controlled Collapsed Chip Connection pads) disposed on the substrate main surface of a wiring board (for example, refer to Patent Document 1) is provided.

Meanwhile, the solder bumps can be formed using, for example, a printing method, a solder ball method (micro-ball method), or the like. The printing method refers to a method in which a solder paste is printed on a plurality of pads formed on the substrate main surface of a wiring board using a metal mask, and then made to reflow, thereby forming solder bumps. The solder ball method refers to a method in which solder balls are disposed and made to reflow on the plurality of pads, thereby forming solder bumps. Meanwhile, in such wiring boards, the solder resist is formed so as to cover the substrate main surface, and a plurality of opening portions which exposes the pads is provided in the solder resist.

### RELATED ART DOCUMENTS

Patent Document 1 is JP-A-11-103160.

### BRIEF SUMMARY OF THE INVENTION

In order to increase the bonding properties between the wiring board and the IC chips, the heights of the respective bumps formed on the pads are preferably similar. In other words, the measurement value of the coplanarity of the respective solder bumps is preferably small. However, in a case in which the solder bumps are formed using the printing method, since the solder bumps are formed using a change of a heated and melted liquid-form solder paste into a spherical shape due to the surface tension, the heights of the solder bumps are determined by the volume of the solder paste. That is, in a case in which the volume of the solder paste is small, it becomes difficult to form high solder bumps. Furthermore, there is a case in which the heights of the respective solder bumps vary (that is, the measurement value of the coplanarity increases) due to a variation in the volume of the printed solder paste. In addition, in a case in which the solder bumps are formed using the solder ball method, when the opening portions in the solder resist have a plurality of internal diameters, for example, it is not possible to dispose solder balls in the opening portions having a small inner diameter, and therefore there is a problem in that it becomes difficult to form the solder bumps. Furthermore, there is a case in which the heights of the respective solder bumps vary due to a variation in the inner diameters of the respective opening portions.

Therefore, there is a possibility that the respective pads and the IC chips may be poorly connected (poor opening, short-circuiting, and the like) even when the solder bumps are formed using the printing method, or the solder bumps are formed using the solder ball method. As a result, the manufactured wiring board becomes an inferior product, and there is a concern that the reliability of the wiring board may degrade.

The invention has been made in consideration of the above problems, and a first object of the invention is to provide a wiring board which is structured to be suitable for connection with components, whereby the reliability can be improved. In addition, a second object of the invention is to provide a manufacturing method preferable for obtaining the above excellent wiring board.

As means for solving the above problems, there is provided a wiring board comprising a plurality of pads disposed in an electrode-forming area on a substrate main surface, and a solder resist which covers the substrate main surface and in which a plurality of opening portions is formed so as to expose the plurality of pads, protrusion-shaped members fixed to some surfaces of the pads, the protrusion-shaped members being formed as separate bodies from the pads having an outer diameter set to be smaller than an outer diameter of the pads, and solder bumps that cover surfaces of the pads and surfaces of the protrusion-shaped members, a height of the solder bumps being larger than a height of the protrusion-shaped members, wherein the plurality of opening portions includes a plurality of different types of opening portions having different internal diameters, and a volume of the protrusion-shaped member disposed in the opening portion increases as an internal diameter of the opening portion decreases.

In addition, as another means for solving the above problems, there is a wiring board comprising a plurality of pads disposed in an electrode-forming area on a substrate main surface, and a solder resist which covers the substrate main surface and in which a plurality of opening portions are formed so as to expose the plurality of pads, the plurality of opening portions located at an outer circumferential portion of the electrode-forming area having an inner diameter set to be smaller than that of the plurality of opening portions located in a central portion of the electrode-forming area, protrusion-shaped members fixed to some surfaces of the pads exposed from the opening portions located in the outer circumferential portion, the protrusion-shaped members being formed as separate bodies from the pads and having an outer diameter set to be smaller than an outer diameter of the pads, and solder bumps that cover surfaces of the pads and surfaces of the protrusion-shaped members, and height of the solder bumps being larger than height of the protrusion-shaped members.

Therefore, according to these wiring boards, the protrusion-shaped members are fixed to some of the surfaces of the pads, the surfaces of the pads and the surfaces of the protrusion-shaped members are covered with the solder bumps, and the height of the solder bumps is larger than the height of the protrusion-shaped members. Therefore, even in a case in which a solder is printed on the pads so as to form the solder bumps, it becomes possible to form high solder bumps. In addition, in a case in which the inner diameter of the opening portions is small, since the volume of the solder that can be filled in the opening portions becomes small, it is difficult to form high solder bumps even when the solder is printed on the exposed pads in the opening portions. Therefore, the volume of the protrusion-shaped member can increase as the internal diameter of the opening portion decreases. Then, even in a case in which the volume of the solder is small, it becomes possible to reliably form high solder bumps using the protrusion-shaped members having a large volume. In addition, the protrusion-shaped members can be fixed to the pads exposed from the opening portions located in the outer circumferential portion of the electrode-forming area. Then, the inner diameter is smaller than that of the opening portions located on the central portion side, and therefore it becomes possible to reliably form high solder bumps by providing the protrusion-shaped members even in the opening portions on the outer circumferential side in which the volume of the solder that can be filled is small. As a result, it is possible to make the heights of the respective solder bumps similar (that is, the measurement value of the coplanarity of the respective solder bumps can be reduced), and therefore it is possible to prevent a poor connection between the respective pads and components. That is, a structure suitable for connection with components is formed, and therefore it becomes possible to improve the reliability of the wiring board.

In addition, since the protrusion-shaped members are formed as separate bodies from the pads, it is possible to form the protrusion-shaped members using a variety of materials. Furthermore, since the outer diameter of the protrusion-shaped members is set to be smaller than the outer diameter of the pads, it becomes easy to form high solder bumps compared to a case in which the outer diameter of the protrusion-shaped members is the same as the outer diameter of the pads or a case in which the outer diameter of the protrusion-shaped members is larger than the outer diameter of the pads. In addition, since the surfaces of the pads and the surfaces of the protrusion-shaped members are covered with the solder bumps, and the heights of the solder bumps are larger than the height of the protrusion-shaped members, it is possible to reliably interpose the solder bumps between the pads (and the protrusion-shaped members) and components when connecting the pads and the components. As a result, the adhesion with the components improves compared to a case in which the solder bumps are not interposed, and therefore it is possible to further improve the reliability of a wiring board.

Here, the “coplanarity” described in the present specification indicates the uniformity on the most bottom surface of a terminal defined in “the standard of the Electronic Industries Association of Japan EIAJ ED-7304, Measuring Method for Package Dimensions of Ball Grid Array (BGA)”. In addition, the “measurement value of coplanarity” refers to a measurement value defined in “ED-7304, Measuring Method for Package Dimensions of Ball Grid Array (BGA)”, and is an index showing the uniformity of the top portions of a plurality of solder bumps with respect to the substrate main surface.

A material that forms the wiring board is not particularly limited, and is arbitrary, and, for example, a resin substrate or the like is preferable. Examples of the preferable resin substrate include substrates made of an EP resin (epoxy resin), a PI resin (polyimide resin), a BT resin (bismaleimide-triazine resin), a PPE resin (polyphenylene ether resin), or the like. In addition, a substrate made of a complex material of the above resin and a glass fiber (woven glass fabric or non-woven glass fabric) maybe used. Specific examples thereof include highly thermal resistant laminated plates, such as a glass-BT complex substrate and a high Tg glass-epoxy complex substrate (FR-4, FR-5, or the like). In addition, a substrate made of a complex material of the above resin and an organic fiber, such as polyamide fiber, may be used. Alternatively, a substrate made of a resin-resin complex material formed by impregnating a thermosetting resin, such as an epoxy resin, in a three-dimensional net-like fluorine-based resin base material, such as continuous porous PTFE, may be used. As an alternative material, it is also possible to select, for example, a variety of ceramics or the like. Meanwhile, the structure of the wiring board is not particularly limited, and examples thereof include a build-up multilayer wiring board having build-up layers on either surface or both surfaces of a core substrate, a coreless wiring board having no core substrate, and the like.

The location and number of the electrode-forming area on the substrate main surface are not particularly limited, and are arbitrary, and, for example, in the case of a so-called multi-cavity substrate, the same number of electrode-forming areas and cavities in a wiring board are present. The electrode-forming area may be present only on the substrate main surface, but may be present on both the substrate main surface and the substrate rear surface.

A plurality of pads that configure the wiring board are disposed in the electrode-forming area. The pads can be formed of a conductive metallic material or the like. Examples of the metallic material which can form the pads include gold, silver, copper, iron, cobalt, nickel, and the like. Particularly, the pads are preferably formed mainly of copper. Then, the resistance of the pads decreases, and the conductivity of the pads improves compared to a case in which the pads are formed mainly of other materials. Furthermore, since the pads are formed mainly of a relatively soft copper, it becomes easy to roughen the pads. In addition, the pads are preferably formed using plating. Then, it is possible to accurately and uniformly form the pads. If the pads are formed using reflow of a metal paste, it can become difficult to highly accurately and uniformly form the pads, and therefore there is a concern that a variation may be caused in the heights of the respective pads.

The solder resist of the wiring board is made of a resin having insulating properties and thermal resistance, and functions as a protective film that covers and hides the substrate main surface so as to protect the substrate main surface. Specific examples of the solder resist include a solder resist made of an epoxy resin, a polyimide resin, or the like. Meanwhile, the cross-sectional shape of the plurality of opening portions formed in the solder resist can be a cross-sectional circular shape, a cross-sectional oval shape, a cross-sectional triangular shape, a cross-sectional rectangular shape, a cross-sectional square shape, or the like.

Furthermore, the protrusion-shaped members of the wiring substrate are fixed to some of the surfaces of the pads. Examples of materials which can form the protrusion-shaped members include copper, silver, iron, cobalt, nickel, and the like, and, in particular, the protrusion-shaped member is preferably formed mainly of copper. Then, the resistance of the protrusion-shaped members decreases, and the conductivity of the protrusion-shaped members improves compared to a case in which the protrusion-shaped members are formed mainly of other materials. Furthermore, since the protrusion-shaped members are formed mainly of relatively soft copper, it becomes easy to roughen the protrusion-shaped members. Meanwhile, the protrusion-shaped members are preferably formed mainly of the same conductive material as the pads. Then, there is no need to prepare a separate material from the pads when forming the protrusion-shaped members. Therefore, the number of materials necessary to manufacture the wiring board decreases, and therefore it becomes possible to reduce the costs for the wiring board. Meanwhile, the shape of the protrusion-shaped members can be a columnar shape, an elliptical shape, a triangular shape, a triangular pyramid shape, a quadrangular shape, a quadrangular pyramid shape, a spherical shape, or the like.

In addition, examples of the method of forming the protrusion-shaped members include a method in which the protrusion-shaped members are formed using plating, and the like. In this case, when the protrusion-shaped member forms a columnar shape, it is possible to easily form the protrusion-shaped members using plating. In addition, in a case in which the protrusion-shaped members are formed mainly of, for example, copper, the protrusion-shaped members are preferably formed using copper plating. Then, the conductivity of the protrusion-shaped members improves compared to a case in which the protrusion-shaped members are formed of, for example, a conductive paste or the like. In addition, the method of forming the protrusion-shaped members additionally includes a method in which a conductive paste is printed on the pads so as to form the protrusion-shaped members, a method in which only a process of attaching a conductive member is carried out on the pads so as to form the protrusion-shaped members, and a method in which a plate material having a larger conductivity than the protrusion-shaped members is attached on the pads, and then etching is carried out on the plate material so as to form the protrusion-shaped members, and the like.

In addition, the height of the protrusion-shaped members is preferably larger than the thickness of the pads. If the height of the protrusion-shaped members is smaller than the thickness of the pads, it can become difficult to form high solder bumps even when the protrusion-shaped members are provided.

Furthermore, it is preferable that a plurality (portion) of the protrusion-shaped members be present in the electrode-forming area (or in the outer circumference portion of the electrode-forming area), and the plurality (portion) of protrusion-shaped members have the same height. Then, since all the protrusion-shaped members can be formed in the same process, it is possible to reduce the manufacturing costs.

Meanwhile, in a case in which the plurality of opening portions include the first opening portion(s) having a predetermined inner diameter and second opening portion(s) having an inner diameter smaller than that of the first opening portion, it is preferable that a plurality (portion) of the protrusion-shaped members be present in the electrode-forming area, and, among the plurality of protrusion-shaped members, the protrusion-shaped members disposed in the second opening portion(s) have a large volume than the protrusion-shaped members disposed in the first opening portion(s). That is, in a case in which the inner diameter of the second opening portion is smaller than the inner diameter of the first opening portion, the volume of the solder bumps formed in the second opening portion becomes smaller than the volume of the solder bumps formed in the first opening portion. As a result, there is a high possibility that the height of the solder bumps formed in the second opening portion becomes smaller than the height of the solder bumps formed in the first opening portion. As a result, since the heights of the respective solder bumps vary, there is a possibility of a poor connection between the solder bumps and the components. Therefore, since the volume of the protrusion-shaped members disposed in the second opening portion can be set to be larger than the volume of the protrusion-shaped members disposed in the first opening portion, the solder bumps formed in the second opening portion become relatively high. In this case, since it becomes possible to make the heights of the respective solder bumps similar even when the solder resist has a plurality of opening portions having different inner diameters, it is possible to improve the connection reliability between the solder bumps and the components. Meanwhile, examples of a method of making the volume of the protrusion-shaped members disposed in the second opening portion larger than the volume of the protrusion-shaped members disposed in the first opening portion include making the height of the protrusion-shaped members disposed in the second opening portion larger than the height of the protrusion-shaped members disposed in the first opening portion, making the outer diameter of the protrusion-shaped members disposed in the second opening portion larger than the outer diameter of the protrusion-shaped members disposed in the first opening portion, making both the height and outer diameter of the protrusion-shaped members disposed in the second opening portion larger than both the height and outer diameter of the protrusion-shaped members disposed in the first opening portion, and the like.

Here, the “inner diameter” of the opening portion (the first opening portion and the second opening portion) refers to the maximum length of the opening portion (maximum diameter). For example, in a case in which the opening portion forms a cross-sectional oval shape, the length of the long diameter of the oval is considered as the inner diameter.

In addition, the surfaces of the pads and the surface of the protrusion-shaped members are preferably roughened. Then, in a case in which the pads are connected to components, the adhesion strength between the surfaces of the pads and the solder bumps becomes high, and the adhesion strength between the surfaces of the protrusion-shaped members and the solder bumps becomes high when heating and melting the solder bumps that cover the surfaces of the pads and the surfaces of the protrusion-shaped members. Therefore, it is possible to more stably support the components using the wiring board.

In addition, the surface roughness Ra of the surfaces of the pads and the surfaces of the protrusion-shaped members is not particularly limited, and is arbitrary, but is, for example, 0.1 μm or more, and preferably 0.1 μm to 0.9 μm. In a case in which the surface roughness Ra is less than 0.1 μm, there is a possibility that it is not possible to increase the adhesion strength between the surfaces of the pads and the solder bumps much, and the adhesion strength between the surfaces of the protrusion-shaped members and the solder bumps. Here, the “surface roughness Ra” described in the present specification refers to the arithmetic mean roughness Ra defined in JIS B0610. Meanwhile, the surface roughness Ra is measured according to JIS B0651.

Meanwhile, the use of the pads is not limited, but the pads are preferably flip chip-connected on connection terminals disposed on the bottom surface side of components by heating and melting the solder bumps that cover the surfaces of the pads and the surfaces of the protrusion-shaped members. That is, the pads for flip chip connection need to be formed to be small in accordance with a decrease in the size of the so-called C4 pads. Therefore, in a case in which the pads are flip chip-connected, the intrinsic problem of, in the present application, a decrease in the reliability of the wiring board caused by a variation in the heights of the solder bumps is liable to occur, and therefore it becomes significantly meaningful to employ embodiments of the present invention.

The solder material used for the solder bumps is not particularly limited, and, for example, a tin-lead eutectic solder (Sn/37Pb: melting point 183° C.) is used. A Sn/Pb-based solder other than the tin-lead eutectic solder, for example, a solder having a composition of Sn/36Pb/2Ag (melting point 190° C.) or the like may be used. In addition, it is also possible to select a lead-free solder, such as a Sn—Ag-based solder, a Sn—Ag—Cu-based solder, a Sn—Ag—Bi-based solder, a Sn—Ag—Bi—Cu-based solder, a Sn—Zn-based solder or a Sn—Zn—Bi-based solder in addition to the above lead-containing solder.

In addition, examples of a preferable component connected with the pads include a capacitor, a resistor, a semiconductor integrated circuit element (IC chip), a micro electro mechanical systems (MEMS) element manufactured using a semiconductor-manufacturing process, and the like. Furthermore, examples of the IC chip include a dynamic random access memory (DRAM), a static random access memory (SRAM), and the like. Here, the “semiconductor integrated circuit element” refers mainly to an element used as a microprocessor or the like of a computer.

Further provided for solving the above problems is a method of manufacturing a wiring board including a laminated portion preparation process of preparing a laminated portion by laminating a plurality of interlayer insulating layers, a pad-forming process of forming a plurality of pads on a substrate main surface by carrying out plating with respect to the uppermost layer of the interlayer insulating layer having the substrate main surface among the plurality of interlayer insulating layers, a protrusion-shaped member-forming process of forming a plurality of protrusion-shaped members on the surfaces of the plurality of pads by carrying out plating with respect to the plurality of pads, a mask disposition process of disposing a mask in which a plurality of opening portions which exposes the plurality of pads and the plurality of protrusion-shaped members on the substrate main surface, and a solder bump-forming process of forming solder bumps in the opening portion by printing solders with respect to the plurality of opening portions in the mask.

Therefore, according to the method of manufacturing the wiring board, the surfaces of the pads and the surfaces of the protrusion-shaped members are covered with the solder bumps by carrying out the solder bump-forming process, and the height of the solder bumps become larger than the height of the protrusion-shaped members. Therefore, even in a method in which the solder bumps are liable to be low if the volume of the solder is small in order to form the solder bumps by printing the solder, it becomes possible to form high solder bumps. In addition, since the volume of the protrusion-shaped members formed in the protrusion-shaped member-forming process is as large as the opening portions of the solder resist having a small inner diameter, even in a case in which the volume of the solder is small in order to form the solder bumps, it becomes possible to reliably form the solder bumps using the protrusion-shaped members having a large volume. As a result, it is possible to make the heights of the respective solder bumps similar (that is, the measurement value of the coplanarity of the respective solder bumps can be reduced), and therefore it is possible to prevent a poor connection between the respective pads and components. That is, since a structure suitable for connection with components is formed, it becomes possible to improve the reliability of the wiring board.

In the laminated portion preparation process, a laminated portion formed by laminating a plurality of interlayer insulating layers is prepared. The interlayer insulating layer can be appropriately selected in consideration of insulating properties, heat resistance, humidity resistance, and the like. Preferable examples of a material which forms the interlayer insulating layer include thermosetting resins, such as an epoxy resin, a phenol resin, a urethane resin, a silicon resin and a polyimide resin, and thermoplastic resins, such as a polycarbonate resin, an acryl resin, a polyacetal resin and a polypropylene resin. Additionally, a complex material of the above resin and a glass fiber (glass woven fabric or glass non-woven fabric) or an organic fiber, such as polyamide fabric, or a resin-resin complex material formed by impregnating a thermosetting resin, such as an epoxy resin, in a three-dimensional net-like fluorine-based resin base material, such as a continuous porous PTFE, may be used. Meanwhile, via holes may be formed in advance in the interlayer insulating layers in order to form via conductors for interlayer connection.

Subsequently, in the pad-forming process, a plurality of pads is formed on the substrate main surface by carrying out plating with respect to the uppermost layer of the interlayer insulating layer, which forms the substrate main surface, among the plurality of interlayer insulating layers. Subsequently, in the protrusion-shaped member-forming process, a plurality of protrusion-shaped members are formed on the surfaces of the plurality of pads by carrying out plating with respect to the plurality of pads. Subsequently, in the mask disposition process, a mask in which a plurality of opening portions which expose the plurality of pads and the plurality of protrusion-shaped members is formed and is disposed on the substrate main surface. Subsequently, in the solder bump-forming process, solder bumps are formed in the opening portion by printing solders with respect to the plurality of opening portions in the mask. A wiring board is manufactured by undergoing the above processes.

### BRIEF DESCRIPTION OF THE DRAWINGS

Illustrative aspects of the invention will be described in detail with reference to the following figures wherein:

FIG. 1 is a schematic cross-sectional view showing the configuration of a coreless wiring board in accordance with an embodiment of the present invention.

FIG. 2 is a schematic plan view showing the coreless wiring board.

FIG. 3 is a main part cross-sectional view showing the coreless wiring board.

FIG. 4 is an explanatory view showing a method of manufacturing the coreless wiring board.

FIG. 5 is an explanatory view showing a method of manufacturing the coreless wiring board.

FIG. 6 is an explanatory view showing a method of manufacturing the coreless wiring board.

FIG. 7 is an explanatory view showing a method of manufacturing the coreless wiring board.

FIG. 8 is an explanatory view showing a method of manufacturing the coreless wiring board.

FIG. 9 is an explanatory view showing a method of manufacturing the coreless wiring board.

FIG. 10 is an explanatory view showing a method of manufacturing the coreless wiring board.

FIG. 11 is an explanatory view showing a method of manufacturing the coreless wiring board.

FIG. 12 is an explanatory view showing a method of manufacturing the coreless wiring board.

FIG. 13 is an explanatory view showing a method of manufacturing the coreless wiring board.

FIG. 14 is a main part cross-sectional view showing a coreless wiring board in accordance with a second embodiment.

FIG. 15 is a main part cross-sectional view showing a coreless wiring board of the second embodiment.

FIG. 16 is a schematic plan view showing a coreless wiring board of the second embodiment.

### DETAILED DESCRIPTION OF EXEMPLARY EMBODIMENTS OF THE INVENTION

A preferred embodiment of the present invention will next be described with reference to the drawings.

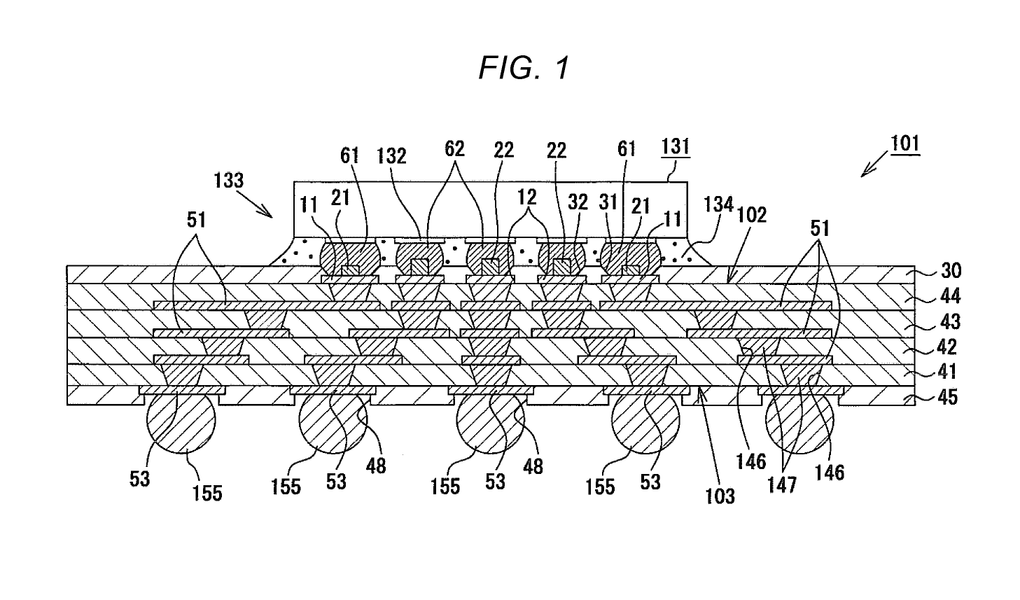

FIG. 1 is a schematic cross-sectional view showing a coreless wiring board 101 (wiring board) of the embodiment. The coreless wiring board 101 does not have a core board, and is a wiring board having a structure in which four resin insulating layers 41, 42, 43 and 44 made of an epoxy resin and conductor layers 51 made of copper are alternatively laminated. The resin insulating layers 41 to 44 are interlayer insulating layers having the same thickness and are made of the same material.

Furthermore, via holes 146 and via conductors 147 are provided respectively in each of the resin insulating layers 41 to 44. Each of the via holes 146 forms an inverted circular truncated cone shape, and the via holes are formed by carrying out a punching process using a YAG laser or a carbonate gas laser with respect to the respective resin insulating layers 41 to 44. Each of the via conductors 147 is a conductor having an expanded diameter in the same direction (the upward direction in FIG. 1), and that is electrically connected to each of the conductor layers 51. The outer diameter A1 (refer to FIG. 3) of each of the via conductors 147 at the top end is set to 50 μm to 120 μm (100 μm in the embodiment), and the outer diameter A2 (refer to FIG. 3) of each of the via conductors 147 at the bottom end is set to 30 μm to 100 μm (60 μm in the embodiment).

As shown in FIG. 1, BGA pads 53 are disposed in an array shape on a substrate rear surface 103 of the coreless wiring board 101 (on the bottom surface of the first layer of the resin insulating layer 41). In addition, the bottom surface of the resin insulating layer 41 is almost entirely covered with a solder resist 45. Opening portions 48 which expose the respective BGA pads 53 are formed in the solder resist 45. A plurality of solder bumps 155 having a height of approximately 400 μm to 600 μm are disposed on the surfaces of the respective BGA pads 53. The respective solder bumps 155 are so-called BGA bumps which are used for electrical connection with terminals on a mother board, not shown.

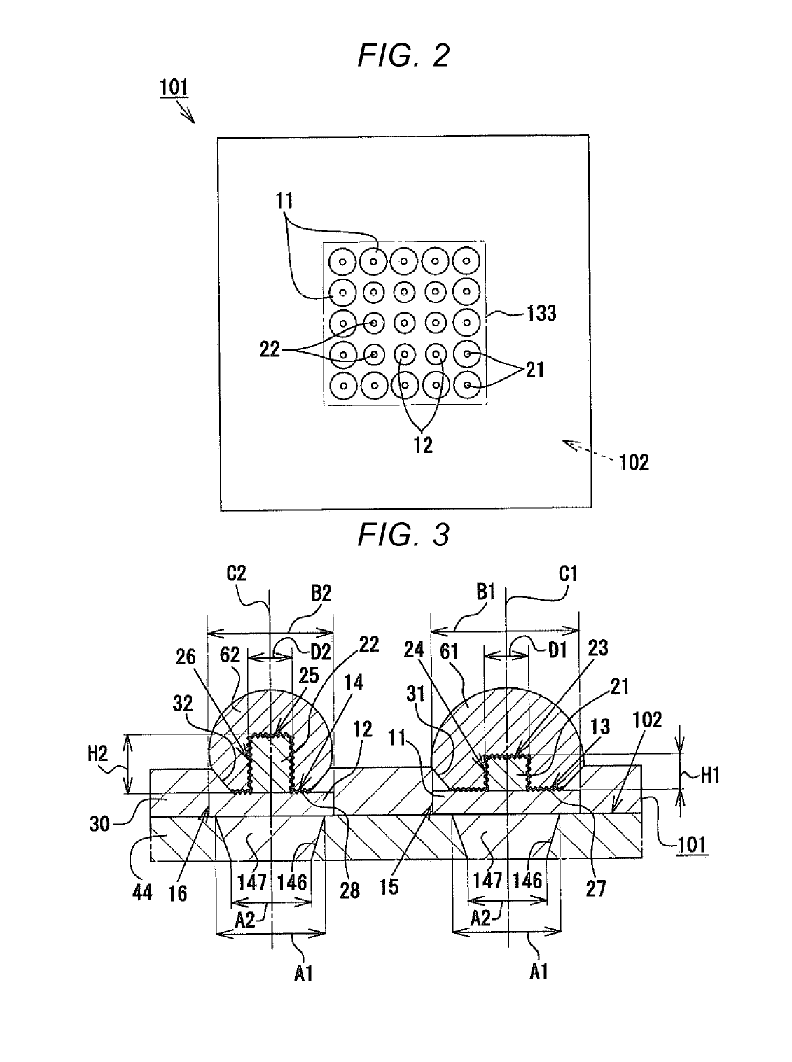

Meanwhile, an electrode-forming area 133 having a substantially rectangular planar shape is set on a substrate main surface 102 (on the surface of the fourth layer of the resin insulating layer 44) of the coreless wiring board 101 as shown in FIG. 2. In addition, a plurality of lines of a plurality of first pads 11 and a plurality of second pads 12 are arrayed vertically and horizontally along the surface direction of the substrate main surface 102 in the electrode-forming area 133. Meanwhile, the pads 11 and 12 of the embodiment form a disk shape. In addition, among the respective pads 11 and 12, the pads located in the outer circumferential portion of the electrode-forming area 133 form first pads 11 and the pads not located in the outer circumferential portion of the electrode-forming area 133 form second pads 12.

As shown in FIG. 3, the outer diameter B1 of each of the first pads 11 is set to 150 μm, and the outer diameter B2 of each of the second pads 12 is set to 130 μm. That is, the outer diameters B1 and B2 of the respective pads 11 and 12 are set to be larger than the outer diameter A1 (100 μm) of the via conductors 147 at the top ends and the outer diameter A2 (60 μm) of the via conductors 147 at the bottom ends. In addition, the thickness of the respective pads 11 and 12 are set to 15 μm. Furthermore, the central axes C1 and C2 of the respective pads 11 and 12 coincide with the central axes of the via conductors 147. Meanwhile, the “central axis C1” refers to an axial line penetrating a place located at the center of the first pad 11 in a plane view, and the “central axis C2” refers to an axial line penetrating a place located at the center of the second pad 12 in a plane view. In addition, the respective pads 11 and 12 are electrically connected to the conductor layers 51 through the via conductors 147 provided in the uppermost layer of the resin insulating layer 44.

As shown in FIG. 3, in the embodiment, areas except the center portions in top surfaces 13 and 14 (surfaces) of the respective pads 11 and 12 and the entire side surfaces 15 and 16 (surfaces) of the respective pads 11 and 12 are roughened. The surface roughness Ra of the roughened portions of the top surfaces 13 and 14 is 0.1 μm to 0.9 μm, and is set to 0.4 μm in the embodiment. Meanwhile, the respective pads 11 and 12 are formed mainly of copper which is a conductive material.

As shown in FIGS. 1 to 3, first protrusion-shaped members 21 are fixed to some of the top surfaces 13 (the center portions of the top surfaces 13 in the embodiment) of the respective first pads 11, and second protrusion-shaped members 22 are fixed to some of the top surfaces 14 (the center portions of the top surfaces 14 in the embodiment) of the respective second pads 12. That is, a plurality of protrusion-shaped members 21 and 22 are present in the electrode-forming area 133. In addition, the first protrusion-shaped members 21 are formed as separate bodies from the first pads 11, and the second protrusion-shaped members 22 are formed as separate bodies from the second pads 12. Furthermore, the number of the first protrusion-shaped member 21 disposed in the first pad 11 is one, and the number of the second protrusion-shaped member 22 disposed in the second pad 12 is one. Therefore, the number of the protrusion-shaped members 21 and 22 becomes the same as the number of the pads 11 and 12. Meanwhile, the protrusion-shaped members 21 and 22 are copper posts formed mainly of copper which is the same conductive material as used for the pads 11 and 12.

As shown in FIG. 3, the surfaces (some of the top surfaces 13 and 14) of the pads 11 and 12 and the surfaces (the front end surfaces 23 and 25, and the side surfaces 24 and 26) of the protrusion-shaped members 21 and 22 are covered with coating layers 27 and 28. The coating layers 27 and 28 are configured of a nickel layer, a palladium layer and gold layer. The nickel layer is a plated layer formed by coating the surfaces of the pads 11 and 12 and the surfaces of the protrusion-shaped members 21 and 22 using non-electrolytic nickel plating. The palladium layer is a plated layer formed by coating the surface of the nickel layer using non-electrolytic palladium plating. The gold layer is a plated layer formed by coating the surface of the nickel layer using non-electrolytic gold plating. In addition, the connection surfaces of the protrusion-shaped members 21 and 22 with the pads 11 and 12 are directly connected to the surfaces of the pads 11 and 12 without passing a medium such as the plated layers. Meanwhile, the coating layers 27 and 28 of the embodiment have a layer structure composed of the nickel layer, the palladium layer and the gold layer, and the layer structure can be appropriately changed.

As shown in FIG. 3, the respective first protrusion-shaped members 21 have an outer diameter D1 set to be the same from the top end to the bottom end, and the first protrusion-shaped member forms a columnar shape as a whole. The outer diameter D1 of the respective first protrusion-shaped members 21 is set to be smaller than the outer diameter B1 (150 μm) of the first pads 11, the outer diameter A1 (100 μm) of the via conductors 147 at the top ends, and the outer diameter A2 (60 μm) of the via conductors 147 at the bottom ends, and is set to 10 μm in the embodiment. In addition, the height H1 of the first protrusion-shaped members 21 is set to be larger than the thickness (15 μm) of the first pads 11, and is set to 20 μm in the embodiment. Therefore, the volume of the first protrusion-shaped member 21 becomes approximately 1570 μm³. In addition, the front end surface 23 (surface) of the first protrusion-shaped member 21 forms a circular shape, and is almost parallel with the top surface 13 of the first pad 11. Furthermore, the central axis of the first protrusion-shaped member 21 coincides with the central axes C1 of the first pads 11 and the central axes of the via conductors 147.

As shown in FIG. 3, the respective second protrusion-shaped members 22 have an outer diameter D2 set to be the same from the top end to the bottom end, and the second protrusion-shaped member forms a columnar shape as a whole. The outer diameter D2 of the respective second protrusion-shaped members 22 is set to be smaller than the outer diameter B2 (130 μm) of the second pads 12, the outer diameter A1 (100 μm) of the via conductors 147 at the top ends, and the outer diameter A2 (60 μm) of the via conductors 147 at the bottom ends, and is set to 10 μm in the embodiment. That is, the outer diameter D2 of the second protrusion-shaped members 22 is set to be the same as the outer diameter D1 of the first protrusion-shaped members 21. In addition, the height H2 of the second protrusion-shaped members 22 is set to be larger than the thickness (15 μm) of the second pads 12, and is set to 35 μm in the embodiment. Therefore, the volume of the second protrusion-shaped member 22 is larger than the volume (approximately 1570 μm³) of the first protrusion-shaped member 21, and becomes approximately 2748 μm³. In addition, the front end surface 25 (surface) of the second protrusion-shaped member 22 forms a circular shape, and is almost parallel with the top surface 14 of the second pad 12. Furthermore, the central axis of the second protrusion-shaped member 22 coincides with the central axes C2 of the second pads 12 and the central axes of the via conductors 147.

As shown in FIG. 3, the front end surfaces 23 and the side surfaces 24 and 26 of the respective protrusion-shaped members 21 and 22 are roughened. The surface roughness Ra of the front end surfaces 23 and 25 and the side surfaces 24 and 26 are the same as the surface roughness Ra of the top surfaces 13 and 14 of the pads 11 and 12, and is set to 0.4 μm in the embodiment.

In addition, the surface (substrate main surface 102) of the resin insulating layer 44 is almost entirely covered with a solder resist 30. First opening portions 31 which expose the first pads 11 and the first protrusion-shaped members 21 and second opening portions 32 which expose the second pads 12 and the second protrusion-shaped members 22 are formed in the solder resist 30. Each of the respective opening portions 31 and 32 forms a mortar shape widening toward the main surface side end portion from the rear surface side end portion of the solder resist 30, and the respective opening portions have different inner diameters. Meanwhile, the inner diameter of the first opening portion 31 at the main surface side end portion is set to 150 μm, and the inner diameter of the second opening portion 32 at the main surface side end portion is set to be a smaller value (130 μm) than the inner diameter of the first opening portion 31 at the main surface side end portion. In addition, the inner diameter of the first opening portion 31 at the rear surface side end portion is set to 110 μm, and the inner diameter of the second opening portion 32 at the rear surface side end portion is set to be a smaller value (90 μm) than the inner diameter of the first opening portion 31 at the rear surface side end portion. Meanwhile, the height H2 of the second protrusion-shaped portion 22 disposed in the opening portion having a small inner diameter (the second opening portion 32) is set to be larger than the height H1 of the first protrusion-shaped member 21 disposed in the opening portion having a large inner diameter (the first opening portion 31).

As shown in FIG. 3, a first solder bump 61 is disposed in each of the first opening portions 31. In detail, the first solder bump 61 covers the entire area exposed in the first opening portion 31 on the top surface 13 of the first pad 11, and covers the entire front end surface 23 and the entire side surface 24 of the first protrusion-shaped member 21. Therefore, the first pads 11 and the first protrusion-shaped members 21 are covered with the first solder bumps 61 so as to be not visible. The height of the first solder bump 61 is larger than the height H1 of the first protrusion-shaped member 21, and is set to 50 μm in the embodiment. In addition, a second solder bump 62 is disposed in each of the second opening portions 32. In detail, the second solder bump 62 covers the entire area exposed in the second opening portion 32 on the top surface 14 of the second pad 12, and covers the entire front end surface 25 and the entire side surface 26 of the second protrusion-shaped member 22. Therefore, the second pads 12 and the second protrusion-shaped members 22 are covered with the second solder bumps 62 so as to be not visible. The height of the second solder bump 62 is set to be larger than the height H2 of the second protrusion-shaped member 22 and to be the same as the height of the first solder bumps 61, and is set to 50 μm in the embodiment. Meanwhile, the solder bumps 61 and 62 in the embodiment are made of a Sn—Ag-based solder which is a lead-free solder. In addition, as shown in FIG. 1, the respective pads 11 and 12 are connected to connection terminals 132 disposed on the bottom surface of an IC chip 131 (component) forming a rectangular plate shape through the solder bumps 61 and 62. That is, the solder bumps 61 and 62 are a so-called C4 bump used for flip chip connection with the connection terminals 132 of the IC chip 131. Meanwhile, the distance from the front end surfaces 23 and 25 of the protrusion-shaped members 21 and 22 to the top portions of the solder bumps 61 and 62 (the surfaces of the connection terminals 132) is preferably 5 μto 80 μm. In the embodiment, the distance from the front end surface 23 of the first protrusion-shaped member 21 to the top portion of the first solder bump 61 is 30 μm, and the distance from the front end surface 25 of the second protrusion-shaped member 22 to the top portion of the second solder bump 62 is 15 μm.

Meanwhile, in the embodiment, among a plurality of first electric paths composed of the first pads 11 and the first solder bumps 61, half form a ground electric path and the other half form a power supply electric path. In addition, a plurality of second electric paths composed of the second pads 12 and the second solder bumps 62 form signal electric paths respectively. The ground electric path, the power supply electric path and the signal electric paths are electrically independent with each other.

As shown in FIG. 1, an underfill 134 is filled in the gap between the substrate main surface 102 and the IC chip 131. As a result, the coreless wiring board 101 and the IC chip 131 are each fixed in a state in which the gap is sealed. Meanwhile, the underfill 134 in the embodiment is made of an epoxy resin having a thermal expansion coefficient of approximately 20 ppm/° C. to 60 ppm/° C. (specifically 34 ppm/° C.).

Next, a method of manufacturing the coreless wiring board 101 will be described.

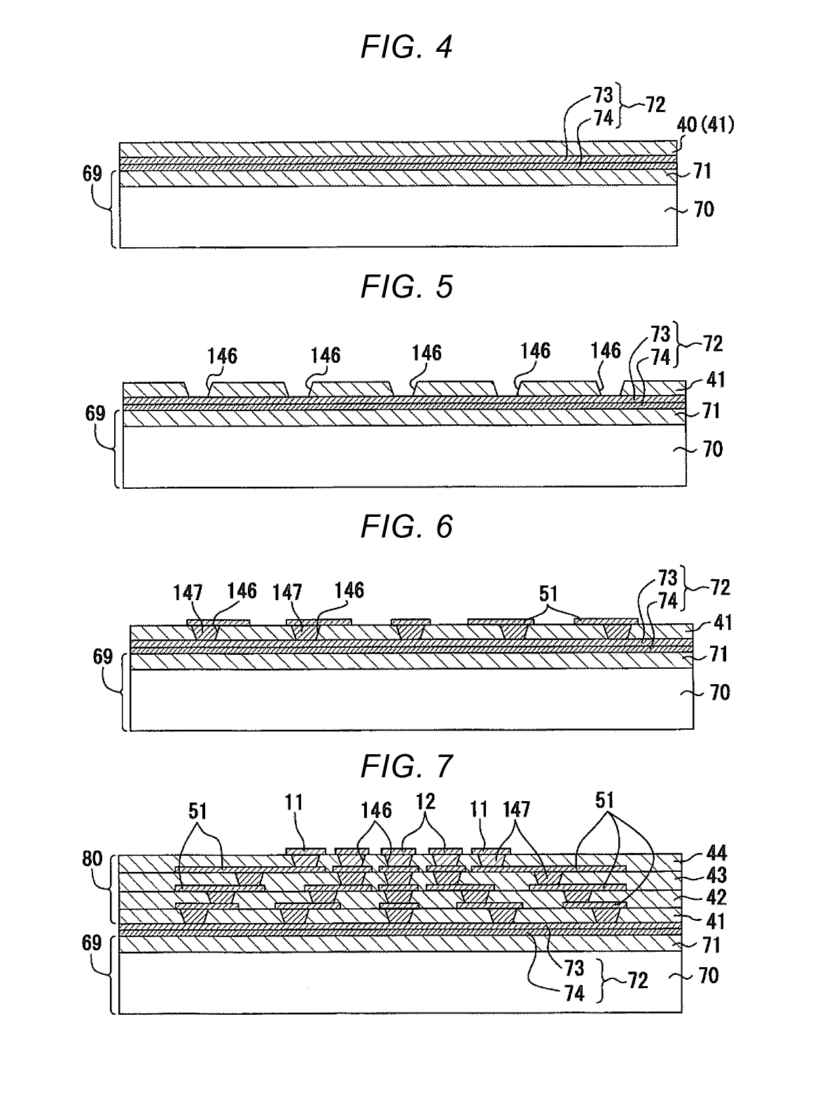

In the laminated portion preparation process, a laminated portion 80, which becomes an intermediate product of the coreless wiring board 101, is manufactured and prepared in advance. Meanwhile, the intermediate product of the coreless wiring board 101 has a structure in which a plurality of product portions, which become the coreless wiring board 101, are arrayed along the planar direction. The intermediate product of the coreless wiring board 101 is manufactured in the following manner. First, a supporting substrate 70 having a sufficient strength, such as a glass epoxy substrate, is prepared (refer to FIG. 4). Next, a sheet-like insulating resin base material made of an epoxy resin is attached on the supporting substrate 70 in a semi-cured state so as to form a foundation resin insulating layer 71, thereby obtaining a base material 69 composed of the supporting substrate 70 and the foundation resin insulating layer 71 (refer to FIG. 4). In addition, a laminated metal sheet body 72 is disposed on a single surface of the base material 69 (specifically on the top surface of the foundation resin insulating layer 71) (refer to FIG. 4). Here, the laminated metal sheet body 72 is disposed on the foundation resin insulating layer 71 in a semi-cured state so that adhesion at which the laminated metal sheet body 72 is not separated from the foundation resin insulating layer 71 is secured in the subsequent manufacturing processes. The laminated metal sheet body 72 is formed by adhering two copper foils 73 and 74 in a separable state. Specifically, the laminate metal sheet body 72 is formed by laminating the respective copper foils 73 and 74 through metal plating (for example, chromium plating).

After that, a sheet-like insulating resin base material 40 is laminated on the laminated metal sheet body 72, heated and pressurized in a vacuum using a vacuum thermo-compression press (not shown) so as to cure the insulating resin base material 40, thereby forming the first layer of the resin insulating layer 41 (refer to FIG. 4). In addition, as shown in FIG. 5, the via holes 146 are formed at predetermined locations of the resin insulating layer 41 by carrying out a laser process, and, subsequently, a desmear treatment which removes smear in the respective via holes 146 is carried out. After that, non-electrolytic copper plating and electrolytic copper plating are carried out according to a well-known method of the related art so that the via conductors 147 are formed in the respective via holes 146. Furthermore, etching is carried out according to a well-known method of the related art (for example, a semi-additive method) so as to form a pattern of conductor layers 51 on the resin insulating layer 41 (refer to FIG. 6). In addition, the second to fourth layers of the resin insulating layers 42 to 44 and the conductor layers 51 are formed using the same method as for the above resin insulating layer 41 and the conductor layers 51, and are laminated on the resin insulating layer 41. Using the following manufacturing processes, a laminated portion 80 is formed by laminating the laminated metal sheet body 72, the resin insulating layers 41 to 44 and the conductor layers 51 on the supporting substrate 70 (refer to FIG. 7). Meanwhile, as shown in FIG. 7, an area located on the laminated metal sheet body 72 becomes the laminated portion 80 which becomes the intermediate product of the coreless wiring board 101.

Subsequently, in the pad-forming process, among the respective resin insulating layers 41 to 44, plating is carried out on the uppermost layer of the resin insulating layer 44 forming the first substrate main surface 102 so as to form the pads 11 and 12 on the substrate main surface 102 (refer to FIG. 7). In the embodiment, patterns of the pads 11 and 12 are formed on the resin insulating layer 44 by carrying out the semi-additive method. Specifically, first, the via holes 146 are formed at predetermined locations in the resin insulating layer 44 by carrying out a laser process, and then a desmear treatment which treats smear in the respective via holes 146 is carried out. Next, after non-electrolytic copper plating is carried out on the surface of the resin insulating layer 44, a dry film is laminated on the resin insulating layer 44 so as to form a first plated resist (not shown). Furthermore, a laser process is carried out on the first plated resist using a laser processor. As a result, opening portions having an inner diameter set to be larger than the outer diameter of the via hole 146 at the top end are formed on locations communicated with the via holes 146 in the resin insulating layer 44. In addition, electrolytic copper plating is carried out, the via conductors 147 are formed in the respective via holes 146, and the pads 11 and 12 made mainly of copper (copper layers) are formed on the top surface of the resin insulating layer 44 exposed through the opening portion (the substrate main surface 102) and the top surfaces of the via conductors 147 exposed through the opening portions. After that, the first plated resist is separated, and unnecessary non-electrolytic copper plated layers are removed. In addition, the thickness of the copper layer is set to approximately 15 μm. The copper layers of the embodiment are formed using plating, but it is possible to form the copper layers using other methods such as a sputtering method or CVD. However, in particular, the copper layers are preferably formed using plating in order to obtain a necessary thickness (15 μm).

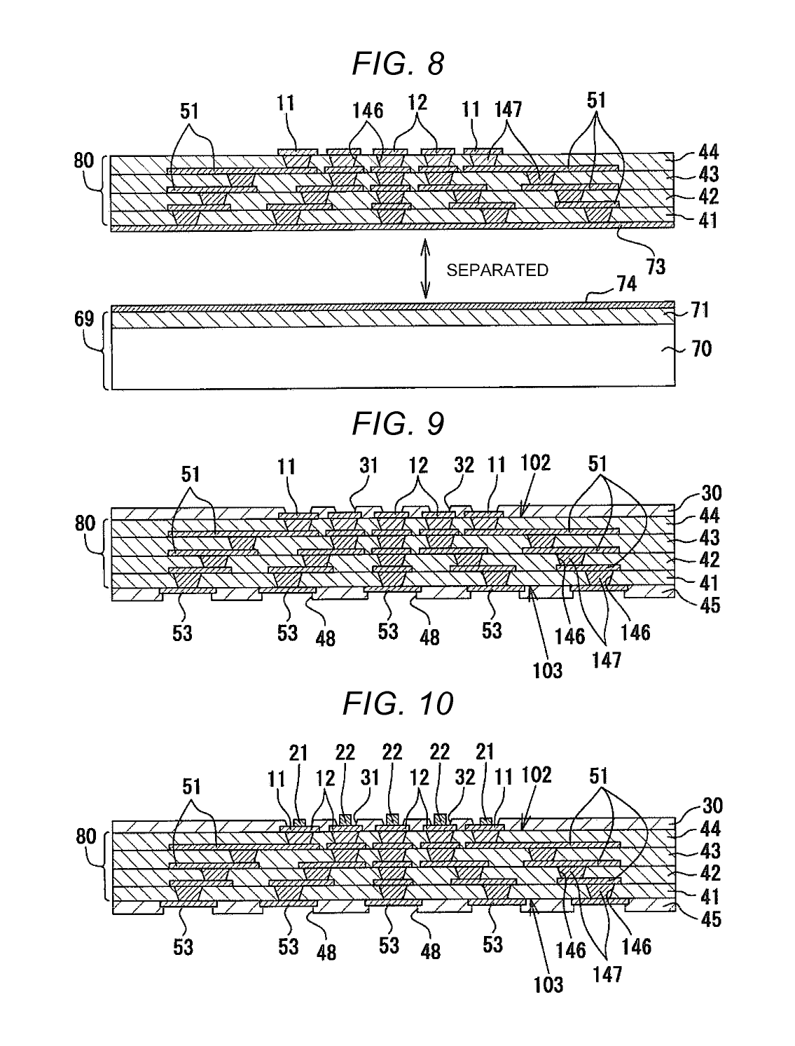

Next, the base material 69 is removed so as to expose the copper foil 73. Specifically, two copper foils 73 and 74 of the laminate metal sheet body 72 are separated at the interface so as to divide the laminated portion 80 from the supporting substrate 70 (refer to FIG. 8). In addition, patterning is carried out using etching on the copper foil 73 present on the substrate rear surface 103 (bottom surface) of the laminated portion 80 (resin insulating layer 41) so as to form the BGA pads 53 in areas on the substrate rear surface 103 on the resin insulating layer 41 (refer to FIG. 9). After that, a photosensitive epoxy resin is coated and cured on the resin insulating layer 41, on which the BGA pads 53 are formed, so as to form the solder resist 45 so as to cover the substrate rear surface 103 of the laminated portion 80 (refer to FIG. 9). Next, exposure and development are carried out in a state in which a predetermined mask is disposed, and the opening portions 48 are patterned in the solder resist 45.

After that, the solder resist 30 is formed by coating and curing a photosensitive epoxy resin on the resin insulating layer 44, on which the pads 11 and 12 are formed, so as to cover the substrate main surface 102 of the laminated portion 80 (refer to FIG. 9). Next, exposure and development are carried out in a state in which a predetermined mask is disposed, and the opening portions 31 and 32 are patterned in the solder resist 30 (refer to FIG. 9).

Subsequently, in the protrusion-shaped member-forming process, plating is carried out on the respective pads 11 and 12 so as to form the protrusion-shaped members 21 and 22 on the top surfaces 13 and 14 of the respective pads 11 and 12 (refer to FIG. 10). Specifically, first, a dry film is laminated on the surface of the solder resist 30 so as to form a second plated resist (not shown). Next, a laser process is carried out on the second plated resist using a laser processor. As a result, opening portions which expose the central portions on the top surfaces 13 of the first pads 11 and the central portions of the top surfaces of the second pads 12 are formed. In addition, electrolytic copper plating is carried out on the top surfaces 13 and 14 of the pads 11 and 12 exposed through the opening portions. At this time, the protrusion-shaped members 21 and 22 made mainly of copper (copper layers) are formed. After that, the second plated resist is separated. Here, the thickness of the copper layer which forms the first protrusion-shaped member 21 is set to approximately 20 μm and the thickness of the copper layer which forms the second protrusion-shaped member 22 is set to approximately 35 μm. Meanwhile, in the embodiment, the copper layers are formed using electrolytic plating, but it is also possible to form the copper layers using other methods such as non-electrolytic plating, a sputtering method or CVD. However, in particularly, the copper layers are preferably formed using plating in order to obtain a necessary thickness (approximately 20 μm and approximately 35 μm).

After that, the surfaces (top surfaces 13) of the first pads 11 and the surfaces (front end surfaces 23 and side surfaces 24) of the first protrusion-shaped members 21 are roughened at the same time. In addition, the surfaces (top surfaces 14) of the second pads 12 and the surfaces (front end surfaces 25 and side surfaces 26) of the second protrusion-shaped members 22 are roughened at the same time. Next, non-electrolytic nickel plating is carried out so as to form the nickel layers on the surfaces of the pads 11 and 12 and the surfaces of the protrusion-shaped members 21 and 22. Furthermore, non-electrolytic palladium plating is carried out so as to form the palladium layer on the nickel layer. In addition, non-electrolytic gold plating is carried out so as to form the gold layer on the palladium layer. Here, the thicknesses of the nickel layer, the palladium layer and the gold layer are set to 0.01 μm to 15 μm. While, the nickel layers, the palladium layers and the gold layers of the embodiment are formed using plating, but it is also possible to form the layers using other methods such as a sputtering method or CVD.

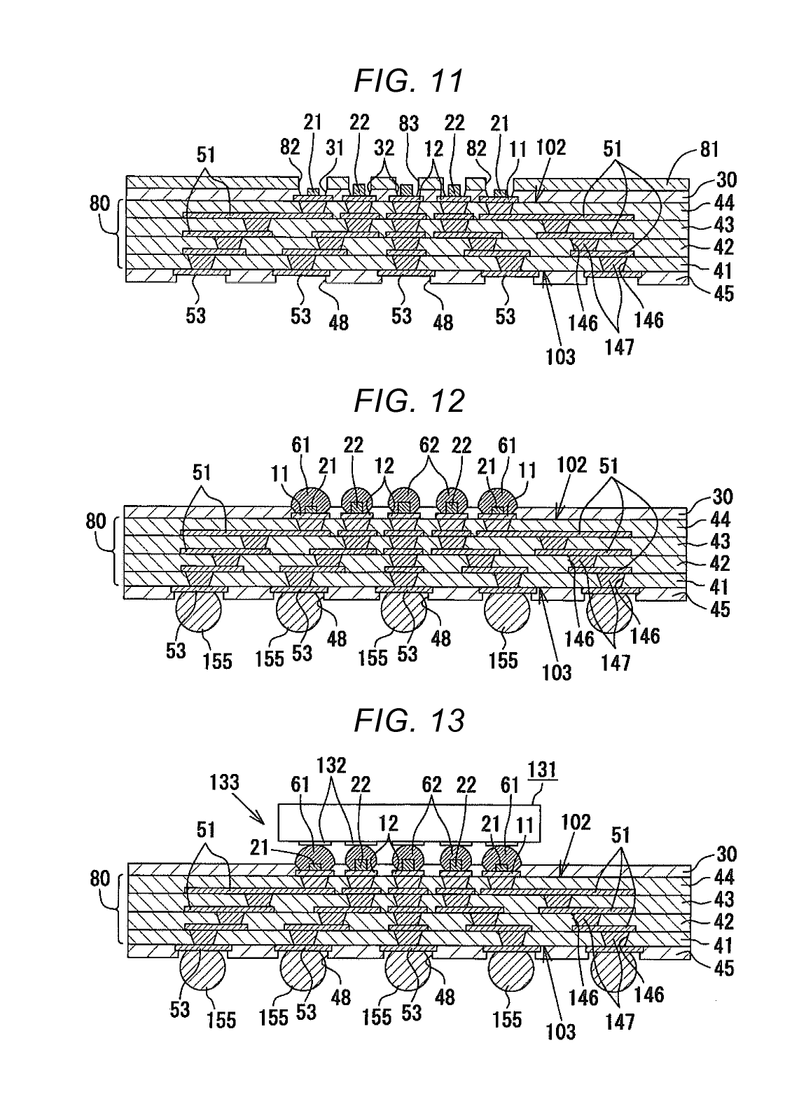

Subsequently, in the mask disposition process, a metal mask 81 (thickness 60 μm) is disposed on the surface of the solder resist 30 (refer to FIG. 11). Next, a punching process and the like are carried out on the metal mask 81 using a drill. As a result, a plurality of first opening portions which expose the first pads 11 and the first protrusion-shaped members 21 is formed at locations communicated with the first opening portions 31 of the solder resist 30 (refer to FIG. 11). In addition, a plurality of second opening portions 83 which expose the second pads 12 and the second protrusion-shaped members 22 is formed at locations communicated with the second opening portions 32 of the solder resist 30 (refer to FIG. 11). Meanwhile, the opening portions 82 and 83 have an inner diameter at the top end side opening set to be the same as the bottom end side opening, and have an inner diameter at the bottom end side opening set to be the same as the inner diameter of the opening portions 31 and 32 at the top end side opening.

Subsequently, in the solder bump-forming process, a solder is printed with respect to the opening portions 82 and 83 in the metal mask 81. In detail, a solder paste is printed on the pads 11 and 12 and the protrusion-shaped members 21 and 22 exposed through the opening portions 82 and 83. At this time, the volume of the solder past filled in the second opening portion 83 becomes smaller than the volume of the solder paste filled in the first opening portion 82. Next, the coreless wiring board 101 on which the solder paste is printed is disposed in a reflow furnace, and heated to a temperature of 10° C. to 40° C. higher than the melting point of the solder. At this time, the solder paste is melted, and the solder bumps 61 and 62 for mounting the IC chip 131 are formed into a semispherical shape in the opening portions 82 and 83. After that, the metal mask 81 is removed (refer to FIG. 12).

Next, the solder bumps 155 are formed on the plurality of BGA pads 53 formed on the substrate rear surface 103 side of the laminated portion 80. Specifically, after solder balls are disposed on the respective BGA pads 53 using a solder ball mounting apparatus, not shown, the solder balls are heated to a predetermined temperature so as to be melted (reflowed), thereby forming the solder bumps 155 on the respective BGA pads 53. Meanwhile, at this time, the intermediate product of the coreless wiring board 101 is completed.

Subsequently, in the division process, the intermediate product of the coreless wiring board 101 is partitioned using a well-known cutting apparatus or the like of the related art. As a result, the product portion is partitioned so that a large number of the coreless wiring boards 101, which are individual products, are obtained at the same time.

After that, the IC chip-mounting process is carried out. Specifically, first, the IC chip 131 is mounted on the electrode-forming area 133 of the coreless wiring board 101 (refer to FIG. 13). At this time, the connection terminals 132 disposed on the bottom surface side of the IC chip 131 are disposed on the solder bumps 61 and 62 disposed on the coreless wiring board 101 side. In addition, the respective solder bumps 61 and 62 are heated to a temperature of approximately 230° C. to 260° C. so as to be melted (reflowed), whereby the pads 11 and 12 are flip chip-connected to the connection terminals 132 so as to mount the IC chip 131 on the coreless wiring board 101. Furthermore, the underfill 134 is filled in the gap between the substrate main surface 102 of the coreless wiring board 101 and the IC chip 131, and a curing treatment is carried out, thereby sealing the gap using a resin.

Therefore, according to the embodiment, it is possible to obtain the following effects.

(1) In the coreless wiring board 101 of the embodiment, the surfaces (top surfaces 13 and 14) of the pads 11 and 12 and the surfaces (front end surfaces 23 and 25 and side surfaces 24 and 26) of the protrusion-shaped members 21 and 22 are covered with the solder bumps 61 and 62, the heights of the solder bumps 61 and 62 are larger than the heights H1 and H2 of the protrusion-shaped members 21 and 22. Therefore, even in a case in which the solder bumps 61 and 62 are liable to become low if the volume of the solder is small in order to form the solder bumps 61 and 62 by printing a solder, it becomes possible to form high solder bumps 61 and 62. Also, in the second opening portions 32 having a small inner diameter, since the volume of the solder that can be filled in the second opening portion 32 also becomes small, even when a solder is printed on the second pads 12 exposed in the second opening portion 32, it is difficult to form high second solder bumps 62. Therefore, in the embodiment, the volumes of the protrusion-shaped members 21 and 22 are made to be large as the opening portions 31 and 32 having a small inner diameter. Therefore, even in a case in which the volume of the solder is small, it becomes possible to reliably form the second solder bumps 62 using the second protrusion-shaped members 22 having a large volume. As a result, it is possible to make the heights of the respective solder bumps 61 and 62 similar (that is, the measurement value of the coplanarity of the respective solder bumps 61 and 62 can be reduced), and it is possible to prevent a poor connection between the respective pads 11 and 12 and the IC chip 131. That is, since a structure suitable for connection with the IC chip 131 is formed, it becomes possible to improve the reliability of the coreless wiring board 101.

(2) In the embodiment, the protrusion-shaped members 21 and 22 are fixed to some of the top surfaces 13 and 14 of the pads 11 and 12, and a protrusion shape is formed as a whole. Therefore, when the solder bumps 61 and 62 which cover the surfaces of the pad 11 and 12 and the surfaces of the protrusion-shaped members 21 and 22 are formed, a state in which the protrusion-shaped members 21 and 22 are fitted in the solder bumps 61 and 62 is formed. As a result, the contact areas between the pads 11 and 12 and the protrusion-shaped members 21 and 22 and the solder bumps 61 and 62 are secured. Therefore, it is possible to increase the adhesion strength between the top surfaces 13 and 14 of the pads 11 and 12 and the solder bumps 61 and 62 or the adhesion strength between the front end surfaces 23 and 25 and side surfaces 24 and 26 of the protrusion-shaped members 21 and 22 and the solder bumps 61 and 62, and, furthermore, it is possible to prevent a poor connection between the respective pads 11 and 12 and the IC chip 131. That is, since the pads 11 and 12 and the protrusion-shaped members 21 and 22 suitable for connection with the IC chip 131 are provided, it becomes possible to improve the reliability of the coreless wiring board 101. Furthermore, since the surfaces of the pads 11 and 12 and the surfaces of the protrusion-shaped members 21 and 22 are roughened, it becomes easy to secure the connection areas between the pads 11 and 12 and the protrusion-shaped members 21 and 22 and the solder bumps 61 and 62. As a result, a poor connection between the pads 11 and 12 and the IC chip 131 is reliably prevented, and therefore it is possible to further improve the reliability of the coreless wiring substrate 101.

(3) In the embodiment, the pads located at the outer circumferential portion of the electrode-forming area 133 are used as the first pads 11, and the pads not located at the outer circumferential portion of the electrode-forming area 133 are used as the second pads 12. Meanwhile, since the second pads 12 are electrodes having a smaller outer diameter than that of the first pads 11, the second solder bumps 62 which cover the second pads 12 are smaller than the first solder bumps 61 which cover the first pads 11. Therefore, it is possible to make the pitch between the second pads 12 finer.

Meanwhile, the embodiment can be changed in the following manner.

The protrusion-shaped members 21 and 22 of the embodiment have the outer diameters D1 and D2 set to be the same from the top end to the bottom end, and form a columnar shape as a whole, but the shape of the protrusion-shaped members is not limited thereto. For example, the outer diameters may be set to increase from the top end toward the bottom end so that the protrusion-shaped members form a cross-sectional frustum shape as a whole. In addition, the outer diameters may be set to increase from the bottom end toward the top end so that the protrusion-shaped members form a cross-sectional inverted frustum shape as a whole.

The protrusion-shaped members 21 and 22 of the embodiment all form the same shape (columnar shape), but the first protrusion-shaped members 21 and the second protrusion-shaped members 22 may have different shapes. For example, the first protrusion-shaped members 21 can form a columnar shape and the second protrusion-shaped members 22 can form a conical shape.

The protrusion-shaped members 21 and 22 of the embodiment are conductors (copper posts) formed using copper plating, but may be conductors formed by printing a copper paste.

In the embodiment, the surfaces (top surfaces 13 and 14) of the pads 11 and 12 and the surface (front end surfaces 23 and 25 and side surfaces 24 and 26) of the protrusion-shaped members 21 and 22 were roughened. The side surfaces 15 and 16 of the pads 11 and 12 can be also roughened. However, only the surfaces of the pads 11 and 12 or only the surface of the protrusion-shaped members 21 and 22 may be roughened.

In the embodiment, the volume of the second protrusion-shaped member 22 was made to be larger than the volume of the first protrusion-shaped member 21 by setting the height H2 of the second protrusion-shaped member 22 to be larger than the height H1 of the first protrusion-shaped member 21. Meanwhile, the outer diameter D2 of the second protrusion-shaped member 22 was set to be the same as the outer diameter D1 of the first protrusion-shaped member 21.

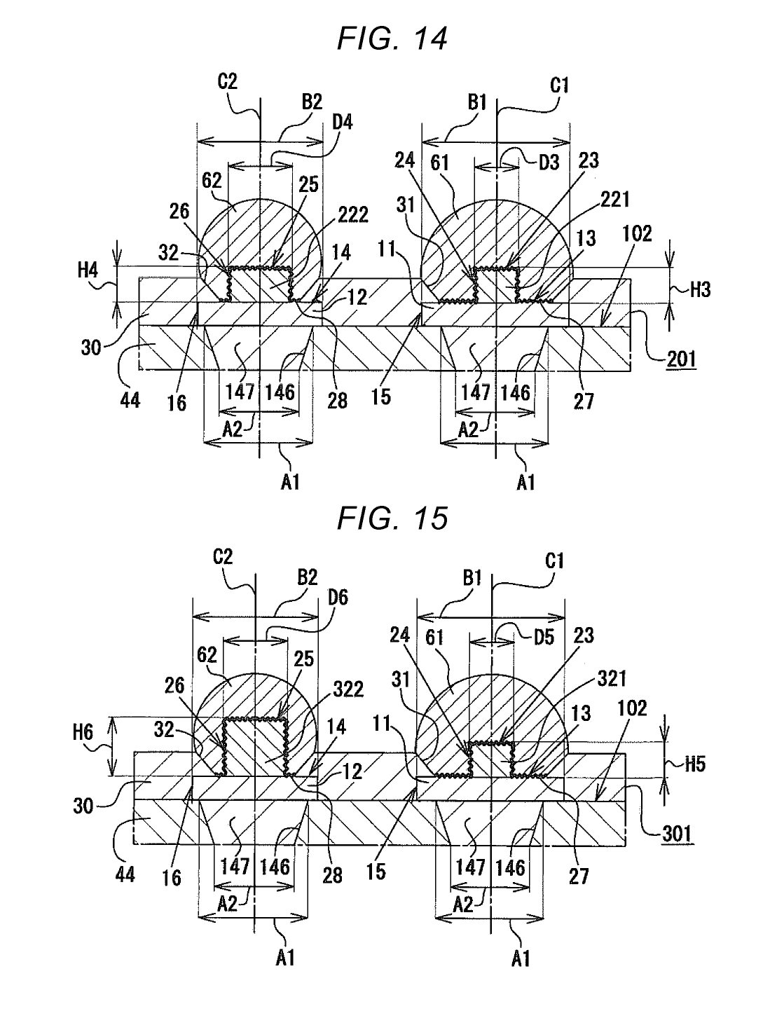

However, as shown in a coreless wiring board 201 of FIG. 14, the volume of a second protrusion-shaped member 222 may be made to be larger than the volume of a first protrusion-shaped member 221 by setting the height H4 of the second protrusion-shaped member 222 to be the same as the height H3 of the first protrusion-shaped member 221, and setting an outer diameter D4 of the second protrusion-shaped member 222 to be larger than an outer diameter D3 of the first protrusion-shaped member 221. Then, it is not necessary to change the plating conditions when the first protrusion-shaped members 221 are formed and when the second protrusion-shaped members 222 are formed, and therefore it is possible to easily form the protrusion-shaped members 221 and 222.

In addition, as shown in a coreless wiring board 301 of FIG. 15, the volume of a second protrusion-shaped member 322 may be made to be larger than the volume of a first protrusion-shaped member 321 by setting the height H6 of the second protrusion-shaped member 322 to be higher than the height H5 of the first protrusion-shaped member 321, and setting an outer diameter D6 of the second protrusion-shaped member 322 to be larger than an outer diameter D5 of the first protrusion-shaped member 321.

In the embodiment, two different types of the first opening portions 31 and the second opening portions 32 having different internal diameters are provided, but three or more different types of the opening portions having different inner diameters may be provided. In this case, as the inner diameter of the opening portion decreases, the volume of the protrusion-shaped member disposed in the opening portion (specifically at least one of the outer diameter and height of the protrusion-shaped member) increases.

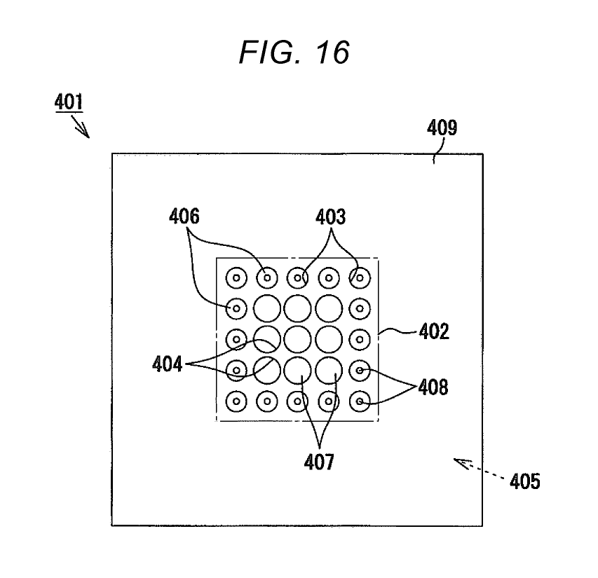

In the embodiment, the inner diameter of the first opening portions 31 located at the outer circumferential portion of the electrode-forming area 133 was set to be larger than the inner diameter of the second opening portions 32 not located at the outer circumferential portion of the electrode-forming area 133. However, for example, as shown in a coreless wiring board 401 of FIG. 16, the inner diameter of a plurality of opening portions 403 located at the outer circumferential portion of an electrode-forming area 402 may be set to be smaller than the inner diameter of a plurality of opening portions 404 located at the central portion (area other than the outer circumferential portion) of the electrode-forming area 402. In addition, in this case, among a plurality of pads 406 and 407 disposed in the electrode-forming area 402 on a substrate main surface 405, protrusion-shaped members 408 may be fixed only to pads 406 exposed from the opening portions 403.

Meanwhile, since wires (not shown) extending outward from the central portion are disposed between the pads 406 adjacent to the outer circumferential portion of the electrode-forming area 402, it is necessary to secure a gap between the pads 406 at the outer circumferential portion to a certain large extent. Therefore, when the outer diameter of the pads 406 located at the outer circumferential portion is made to be smaller than the outer diameter of the pads 407 located at the central portion, it is possible to obtain a design in which a large gap is secured between the pads 406. In addition, since the size of the opening portions formed in a solder resist 409 is set according to the size of the pads, when the above design is employed, the inner diameter of the opening portions 403 located at the outer circumferential portion becomes smaller than the inner diameter of the opening portions 404 located at the central portion (refer to FIG. 16). However, even when a solder is printed on the pads 406 exposed in the opening portions 403, it is difficult to form high solder bumps (not shown). Therefore, in FIG. 16, the solder bumps at the outer circumferential portion are formed to be high by forming the protrusion-shaped portions 408 only at the outer circumferential portion of the electrode-forming area 402.

In the coreless wiring board 101 of the embodiment, the pads 11 and 12 and the protrusion-shaped members 21 and 22 are formed only on the substrate main surface 102, but is not limited to this configuration. For example, the pads 11 and 12 and the protrusion-shaped members 21 and 22 may be formed on both the substrate main surface 102 and the substrate rear surface 103.

In the embodiment, the package type of the coreless wiring board 101 was a ball grid array (BGA), but is not limited only to the BGA, and may be, for example, a pin grid array (PGA), a land grid array (LGA), or the like.

Next, the technical ideas understood using the above specific embodiments will be listed as follows.

(1) A wiring board in which the height of the protrusion-shaped members is larger than the thickness of the pads.

(2) A wiring board in which the pads are flip chip-connected to a plurality of connection terminals disposed on the bottom surface side of a component by heating and melting solder bumps which cover the surfaces of the pads and the surfaces of the protrusion-shaped members, and the distance from the front end surface which configures the surface of the protrusion-shaped member to the top portion of the solder bump and the distance from the front end surface to the surface of the connection terminal is 5 μm to 80 μm.

(3) A wiring board which does not have a core substrate, has the substrate main surface and the substrate rear surface, and has a laminated portion formed by laminating a plurality of interlayer insulating layers, in which via conductors provided in the interlayer insulating layers radially expand toward the substrate main surface side, and the outer diameter of the pads is set to be larger than the outer diameter of the via conductors on the substrate main surface side.

(4) A wiring board in which at least one of the outer diameter and height of the protrusion-shaped members is set according to the inner diameter of the opening portions, the plurality of opening portions is configured by including first opening portions having a predetermined inner diameter and second opening portions having a smaller inner diameter than the first opening portions, a plurality of the protrusion-shaped members is present in the electrode-forming area, and, among the plurality of protrusion-shaped members, the protrusion-shaped members disposed in the second opening portions have at least one of the outer diameter and height larger than the protrusion-shaped members disposed in the first opening portions.

(5) A wiring board having a plurality of pads disposed in an electrode-forming area on a substrate main surface and a solder resist which covers the substrate main surface and in which a plurality of opening portions which exposes the plurality of pads is formed, in which the protrusion-shaped members are fixed to some of the surfaces of the pads, the protrusion-shaped members are formed as separate bodies from the pads, have an outer diameter set to be smaller than the outer diameter of the pads, the surfaces of the pads and the surfaces of the protrusion-shaped members are covered with solder bumps, the pads are flip chip-connected to a plurality of connection terminals disposed on the bottom surface side of a component by heating and melting the solder bumps which cover the surfaces of the pads and the surfaces of the protrusion-shaped members, and the height of the solder bumps is larger than the height of the protrusion-shaped member in a state in which the pads are flip chip-connected to the connection terminals.

### DESCRIPTION OF REFERENCE NUMERALS

11: FIRST PAD AS PAD

12: SECOND PAD AS PAD

13 and 14: TOP SURFACE AS SURFACE OF PAD

15 and 16: SIDE SURFACE AS SURFACE OF PAD

21, 221, and 321: FIRST PROTRUSION-SHAPED MEMBER AS PROTRUSION-SHAPED MEMBER

22, 222, and 322: SECOND PROTRUSION-SHAPED MEMBER AS PROTRUSION-SHAPED MEMBER

23 and 25: FRONT END SURFACE AS SURFACE OF PROTRUSION-SHAPED MEMBER

24 and 26: SIDE SURFACE AS SURFACE OF PROTRUSION-SHAPED MEMBER

30 and 409: SOLDER RESIST

31: FIRST OPENING PORTION AS OPENING PORTION OF SOLDER RESIST

32: SECOND OPENING PORTION AS OPENING PORTION OF SOLDER RESIST

41, 42, 43, and 44: RESIN INSULATING LAYER AS INTERLAYER INSULATING LAYER

61: FIRST SOLDER BUMP AS SOLDER BUMP

62: SECOND SOLDER BUMP AS SOLDER BUMP

80: LAMINATED PORTION

81: METAL MASK AS MASK

82: FIRST OPENING PORTION AS OPENING PORTION OF MASK

83: SECOND OPENING PORTION AS OPENING PORTION OF MASK

101, 201, 301, and 401: CORELESS WIRING BOARD AS WIRING BOARD

102 and 405: SUBSTRATE MAIN SURFACE

131: IC CHIP AS COMPONENT

132: CONNECTION TERMINAL

133 and 402: ELECTRODE FORMING AREA

403 and 404: OPENING PORTION OF SOLDER RESIST

406 and 407: PAD

408: PROTRUSION-SHAPED MEMBER

B1 and B2: OUTER DIAMETER

D1, D2, D3, D4, D5, and D6: OUTER DIAMETER OF PROTRUSION-SHAPED MEMBER

H1, H2, H3, H4, H5, and H6: HEIGHT OF PROTRUSION-SHAPED MEMBER

What is claimed is:

1. A wiring board, comprising:
a plurality of pads disposed in an electrode-forming area on a substrate main surface;
a solder resist which covers the substrate main surface and in which a plurality of opening portions which exposes the plurality of pads are formed;
protrusion-shaped members fixed to some surfaces of the pads, the protrusion-shaped members being formed as separate bodies from the pads and having an outer diameter set to be smaller than an outer diameter of the pads; and
solder bumps that cover surfaces of the pads and surfaces of the protrusion-shaped members, heights of the solder bumps being larger than heights of the protrusion-shaped members, wherein
the plurality of opening portions include a plurality of different types of opening portions having different internal diameters, and a volume of the protrusion-shaped member disposed in the opening portion increases as an internal diameter of the opening portion decreases.

2. The wiring board according to claim 1, wherein a portion of the protrusion-shaped members are present in the electrode-forming area, and the portion of protrusion-shaped members have the same height.

3. The wiring board according to claim 1, wherein:
the plurality of opening portions include first opening portions having a predetermined inner diameter and second opening portions having a smaller inner diameter than the first opening portions,
a portion of the protrusion-shaped members are present in the electrode-forming area, and
the protrusion-shaped members disposed in the second opening portions have a larger volume than the protrusion-shaped members disposed in the first opening portions.

4. The wiring board according to claim 1, wherein the protrusion-shaped members are formed mainly of the same conductive material as the pads.

5. The wiring board according to claim 1, wherein the surfaces of the pads and the surfaces of the protrusion-shaped members are roughened.

6. The wiring board according to claim 1, wherein the pads are flip chip-connected to a plurality of connection terminals disposed on a bottom surface side of a component by heating and melting the solder bumps which cover the surfaces of the pads and the surfaces of the protrusion-shaped members.

7. A method of manufacturing a wiring board, comprising:
a laminated portion preparation process of preparing a laminated portion by laminating a plurality of interlayer insulating layers;
a pad-forming process of forming a plurality of pads on a substrate main surface by carrying out plating on an uppermost layer of the interlayer insulating layer having the substrate main surface among the plurality of interlayer insulating layers;
a protrusion-shaped member-forming process of forming a plurality of protrusion-shaped members on the surfaces of the plurality of pads by carrying out plating on the plurality of pads;
a mask disposition process of disposing a mask in which a plurality of opening portions which expose the plurality of pads and the plurality of protrusion-shaped members is formed on the substrate main surface; and
a solder bump-forming process of forming solder bumps in the opening portions by printing a solder with respect to the plurality of opening portions in the mask.

8. A wiring board, comprising:
a plurality of pads disposed in an electrode-forming area on a substrate main surface; and
a solder resist which covers the substrate main surface and in which a plurality of opening portions which exposes the plurality of pads are formed, the plurality of opening portions located at an outer circumferential portion of the electrode-forming area having an inner diameter set to be smaller than that of the plurality of opening portions located at a central portion of the electrode-forming area;
protrusion-shaped members fixed to some surfaces of the pads exposed from the opening portions located at the outer circumferential portion, the protrusion-shaped members being formed as separate bodies from the pads and having an outer diameter set to be smaller than an outer diameter of the pads; and
solder bumps that cover surfaces of the pads and surfaces of the protrusion-shaped members, heights of the solder bumps being larger than heights of the protrusion-shaped members.

9. The wiring board according to claim 8, wherein a plurality of the protrusion-shaped members are present in the outer circumferential portion of the electrode-forming area, and the plurality of protrusion-shaped members have the same height.

10. The wiring board according to claim 8, wherein the protrusion-shaped members are formed mainly of the same conductive material as the pads.

11. The wiring board according to claim 8, wherein the surfaces of the pads and the surfaces of the protrusion-shaped members are roughened.

12. The wiring board according to claim 8, wherein the pads are flip chip-connected to a plurality of connection terminals disposed on a bottom surface side of a component by heating and melting the solder bumps which cover the surfaces of the pads and the surfaces of the protrusion-shaped members.
